(19) United States
(12) Patent Application Publication
(10) Pub. No.: US 2025/0197694 A1
(43) Pub. Date: Jun. 19, 2025

(54) THERMALLY-CONDUCTIVE ELECTRICAL CONDUCTING LAYER

(71) Applicant: TATSUTA ELECTRIC WIRE & CABLE CO., LTD., Osaka (JP)

(72) Inventors: Yuusuke HARUNA, Kyoto (JP); Hiroshi TAJIMA, Kyoto (JP); Tomohiro NAGATAKE, Kyoto (JP)

(21) Appl. No.: 18/849,255

(22) PCT Filed: Mar. 22, 2023
(86) PCT No.: PCT/JP2023/011136

§ 371 Date: Sep. 20, 2024

(30) Foreign Application Priority Data
Mar. 24, 2022 (JP) 2022-048240

(51) Int. Cl. C09J 9/02; C09J 7/00; C09J 11/04; C09K 5/14

(52) U.S. Cl. CPC C09J 9/02; C09J 7/00; C09J 11/04; C09K 5/14; C09J 2203/326; C09J 2301/408; C09J 2463/00

(57) ABSTRACT

Provided is a thermally-conductive electrical conducting layer having excellent thermal conductivity in the thickness direction. A thermally-conductive electrical conducting layer (1) is a thermally-conductive electrical conducting layer containing a binder component (11) and electrical conducting particles (12). The electrical conducting particles (12) include electrical conducting particles A (12a) having a median diameter larger than a thickness (T) of the thermally-conductive electrical conducting layer (1) and having a thermal conductivity of 20 W/mK or more, and electrical conducting particles B (12b) having a median diameter smaller than the thickness (T) of the thermally-conductive electrical conducting layer (1). The resistivity of the thermally-conductive electrical conducting layer (1) is 2.0×10⁻⁵Ω·m or more.

### TECHNICAL FIELD

The present disclosure relates to a thermally-conductive electrical conducting layer.

### BACKGROUND ART

In printed circuit boards, electrical conducting adhesives are frequently used. Examples thereof include electrical conducting adhesive sheets (electrical conducting bonding films) that are used to electrically connect an electromagnetic wave shielding film disposed on a printed circuit board and the external ground or a reinforcing member that is intended to ground circuits.

As an electrical conducting adhesive sheet that is used in printed circuit boards, for example, an electrical conducting sheet equipped with an electrical conducting layer containing at least a thermosetting resin and dendrite-shaped electrical conducting fine particles, in which the thickness of the electrical conducting layer satisfies a specific condition, the average particle diameter D50 of the dendrite-shaped electrical conducting fine particles is not less than 3 μm and not more than 50 μm, and the dendrite-shaped fine particles are contained in the electrical conducting layer in a range of not less than 50% by weight and not more than 90% by weight (refer to Patent Literature 1).

The printed circuit boards are used with electronic components mounted thereon. Recently, the size reduction and functional improvement of electronic components have been in progress, and there has been a tendency that the amount of heat generated from semiconductor elements increases. When exposed to high-temperature environments for a long period of time, electronic components become incapable of exhibiting the original functions, and the service life thereof deteriorates. Therefore, in electrical conducting adhesive sheets that are applied to printed circuit boards, there are cases where a highly heat-dissipating joining material is used to efficiently diffuse heat that is generated from semiconductor elements.

In Patent Literature 2 and 3, thermally conductive sheets in which the long axis direction of a thermally conductive filler, such as graphite particles or hexagonal boron nitride particles, is oriented in the thickness direction of the thermally conductive sheet are disclosed.

### CITATION LIST

### Patent Literature

Patent Literature 1: International Publication No. WO. 2012/164925
Patent Literature 2: Japanese Patent Laid-Open No. 2011-162642
Patent Literature 3: Japanese Patent Laid-Open No. 2012-38763

### SUMMARY OF INVENTION

### Technical Problem

However, in conventional electrical conducting adhesive sheets having excellent electrical conductivity and heat dissipation, the thermal conductivity is approximately equal in the plane direction and in the thickness direction or the thermal conductivity in the plane direction is high, but the thermal conductivity in the thickness direction is low.

Therefore, it is an object of the present disclosure to provide a thermally-conductive electrical conducting layer having excellent thermal conductivity in the thickness direction.

### Solution to Problem

The present disclosure provides a thermally-conductive electrical conducting layer including a binder component and electrical conducting particles, wherein the electrical conducting particles include electrical conducting particles A having a median diameter larger than a thickness of the thermally-conductive electrical conducting layer and having a thermal conductivity of 20 W/mK or more, and electrical conducting particles B having a median diameter smaller than the thickness of the thermally-conductive electrical conducting layer, and a resistivity is 2.0×10⁻⁵Ω·m or more.

The electrical conducting particle A are preferably disposed to be aligned in a plane direction of the thermally-conductive electrical conducting layer as primary particles or aggregates of primary particles.

The electrical conducting particle A are preferably disposed to be dotted as primary particles or aggregates of primary particles.

A thermal conductivity in a thickness direction of the thermally-conductive electrical conducting layer is preferably 5.0 W/mK or more.

An electrical resistance value in the thickness direction of the thermally-conductive electrical conducting layer is preferably 0.1Ω or less.

A median diameter of the electrical conducting particles A is 105% to 1000% based on the thickness of the thermally-conductive electrical conducting layer, and a median diameter of the electrical conducting particles B is 5% to 80% based on the thickness of the thermally-conductive electrical conducting layer.

### Advantageous Effects of Invention

The thermally-conductive electrical conducting layer of the present disclosure has excellent thermal conductivity in the thickness direction. Therefore, for example, when the thermally-conductive electrical conducting layer is used for adhesion between a ground circuit and a reinforcing member on the grounding side, a printed circuit board having excellent thermal conductivity in the thickness direction and having both electrical conductivity and high heat dissipation can be obtained.

### BRIEF DESCRIPTION OF DRAWINGS

FIG. 1 is a partial cross-sectional view showing one embodiment of a thermally-conductive electrical conducting layer of the present disclosure.

FIG. 2 is a top view of the thermally-conductive electrical conducting layer shown in FIG. 1.

FIG. 3 is a partial cross-sectional view showing another embodiment of the thermally-conductive electrical conducting layer of the present disclosure.

FIG. 4 is a top view of the thermally-conductive electrical conducting layer shown in FIG. 3.

FIG. 5 is a partial cross-sectional view showing one embodiment of a printed circuit board with a reinforcing member to which the thermally-conductive electrical conducting layer of the present disclosure is applied.

FIG. 6 is a top view showing a test piece from which a surface resistance value is measured in Examples.

FIG. 7 is a cross-sectional view of the test piece shown in FIG. 6.

### DESCRIPTION OF EMBODIMENTS

### [Thermally-Conductive Electrical Conducting Layer]

A thermally-conductive electrical conducting layer of the present disclosure includes at least a binder component and electrical conducting particles. In addition, the electrical conducting particles include electrical conducting particles (electrical conducting particles A) having a median diameter larger than the thickness of the thermally-conductive electrical conducting layer and having a thermal conductivity of 20 W/mK or more, and electrical conducting particles (electrical conducting particles B) having a median diameter smaller than the thickness of the thermally-conductive electrical conducting layer. For each of the binder component, the electrical conducting particles A, and the electrical conducting particles B, only one type may be used, or two or more types may be used.

The thermally-conductive electrical conducting layer is preferably an adhesive layer in which a resin portion composed of the binder component is capable of exhibiting adhesiveness. That is, the thermally-conductive electrical conducting layer is preferably a thermally-conductive electrical conducting adhesive layer. In addition, the thermally-conductive electrical conducting layer may be isotropically conductive or anisotropically conductive.

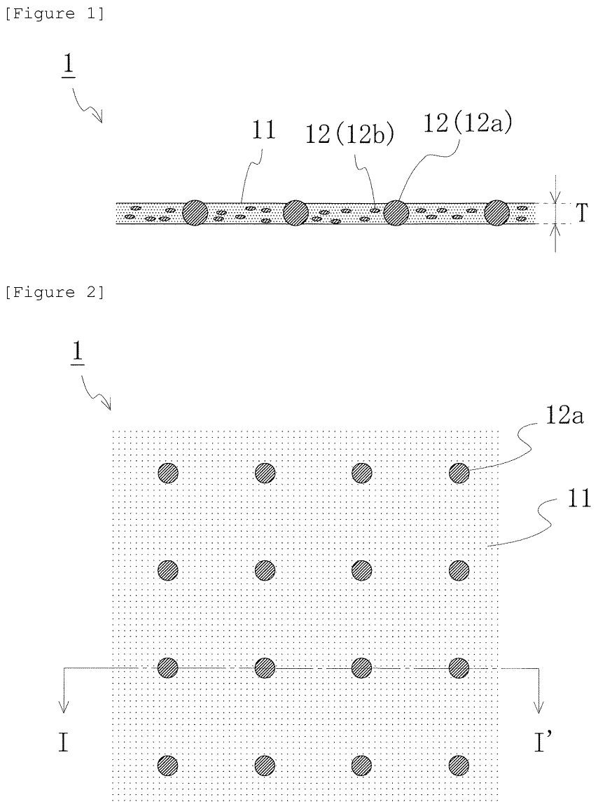

FIG. 1 shows one embodiment of the thermally-conductive electrical conducting layer of the present disclosure. A thermally-conductive electrical conducting layer (1) is layered (sheet-shaped) and includes a binder component (11) and electrical conducting particles (12). The electrical conducting particles (12) include electrical conducting particles A (12a) and electrical conducting particles B (12b). The median diameter of the electrical conducting particles A (12a) is larger than the thickness (T) of the thermally-conductive electrical conducting layer (1), and at least a part of the electrical conducting particles A (12a) thus protrudes from the surface of a resin layer composed of the binder component (11). On the other hand, the median diameter of the electrical conducting particles B (12b) is smaller than the thickness (T) of the thermally-conductive electrical conducting layer (1).

### (Electrical Conducting Particles A)

As described above, the thermally-conductive electrical conducting layer includes the electrical conducting particles A having a median diameter larger than the thickness of the thermally-conductive electrical conducting layer and having a thermal conductivity of 20 W/mK or more. The thickness of the thermally-conductive electrical conducting layer refers to the thickness in the region in which the electrical conducting particles in the resin layer portion composed of the binder component do not protrude in a state before the binder component flows (for example, the thickness T shown in FIG. 1). As used herein, the median diameter of the electrical conducting particles A refers to, when the electrical conducting particles A are compressed, the median diameter in a state before compression.

The median diameter of the electrical conducting particles A is more than 100%, preferably 105% or more, and more preferably 110% or more based on the thickness of the thermally-conductive electrical conducting layer. The median diameter of the electrical conducting particles A is larger than the thickness of the thermally-conductive electrical conducting layer, which makes a part of the electrical conducting particles A exposed on the surface of the thermally-conductive electrical conducting layer and makes the thermal conductivity and the electrical conductivity in the thickness direction of the thermally-conductive electrical conducting layer excellent.

The median diameter of the electrical conducting particles A is preferably 1000% or less, more preferably 900% or less, further preferably 750% or less, and particularly preferably 500% or less of the thickness of the thermally-conductive electrical conducting layer. When the median diameter of the electrical conducting particles A is 1000% or less, the close adhesion strength to an object is better.

The median diameter of the electrical conducting particles A is preferably 1 to 90 μm, more preferably 5 to 75 μm, and further preferably 10 to 45 μm. When the median diameter is 1 μm or more, the thermal conductivity and the electrical conductivity in the thickness direction are more exhibited by the electrical conducting particles A. In addition, the dispersibility of the electrical conducting particles A is good, and aggregation can be suppressed. When the median diameter is 90 μm or less, the close adhesion strength of the thermally-conductive electrical conducting layer to an object is better.

In the present specification, the median diameter (D50) of the electrical conducting particles is the number-based average primary particle diameter that is measured by the laser diffraction/scattering method.

The thermal conductivity of the electrical conducting particles A is 20 W/mK or more. This makes the thermally-conductive electrical conducting layer excellent in terms of thermal conductivity in the thickness direction. The thermal conductivity is a thermal conductivity at 300 K. Examples of the electrical conducting particles A include metal particles, metal-coated resin particles, metal fibers, carbon fillers, and carbon nanotubes.

Examples of metal constituting the metal particles and the coated portion of the metal-coated resin particles include gold, silver, copper, nickel, zinc, indium, tin, lead, bismuth, and alloys containing two or more thereof. Only one of the metal may be used, or two or more of the metals may be used.

Specific examples of the metal particles include copper particles, silver particles, nickel particles, silver-coated copper particles, indium particles, tin particles, lead particles, gold-coated copper particles, silver-coated nickel particles, gold-coated nickel particles, indium-coated copper particles, tin-coated copper particles, lead-coated copper particles, bismuth-coated copper particles, indium-coated nickel particles, tin-coated nickel particles, bismuth-coated nickel particles, and silver-coated alloy particles. Examples of the silver-coated alloy particles include silver-coated copper alloy particles in which alloy particles including copper (for example, copper alloy particles including an alloy of copper, nickel, and zinc) are coated with silver. The metal particles can be made by an electrolysis method, an atomization method, a reduction method, or the like.

Among them, the electrical conducting particles A are preferably metal particles having a 20% compressive strength of 1.0 to 25 MPa in a 170° C. environment. The compressive strength is more preferably 5.0 to 23 MPa, and further preferably 11 to 22 MPa. When the electrical conducting particles A is metal particles having a compressive strength within the above range, the particles are moderately compressed when high pressure is applied in a high temperature environment, the particle shape can be maintained, and the thermal conductivity and the electrical conductivity in the thickness direction are better. The 20% compressive strength of the metal particles is measured in accordance with JIS Z 8844:2019. The compressive strength refers to, when the electrical conducting particles A are compressed, the compressive strength in a state before compression.

The electrical conducting particles A preferably include at least tin as a constituent metal. The content of tin in the electrical conducting particles A is preferably 80% by mass or more, more preferably 85% by mass or more, further preferably 90% by mass or more, and particularly preferably 94% by mass or more based on 100% by mass of the total amount of the electrical conducting particles A. It is presumed that tin in the electrical conducting particles A forms alloys with objects having electrical conductivity (a ground circuit, a reinforcing member on the ground side, and the like) at the interface during thermocompression bonding. Therefore, when the electrical conducting particles A include 80% by mass or more (in particular, 90% by mass or more) of tin, the connection stability between objects is maintained even when the thermally-conductive electrical conducting layer is subjected to high temperature in a reflow step or the like. The content is preferably 99.9% by mass or less, and more preferably 99.6% by mass or less. When the content is 99.9% by mass or less, the electrical conducting particles A have a certain degree of hardness, and the electrical conducting particles A are not too compressed when high pressure is applied in a high temperature environment, and it is easy to ensure conduction between objects.

As a constituent metal of the metal particles containing tin, a further metal other than tin may be contained. Examples of the further metal include gold, silver, copper, platinum, nickel, zinc, lead, palladium, bismuth, antimony, and indium. The metal particles containing tin preferably include a metal harder than tin, such as gold, silver, copper, platinum, nickel, or palladium, as the further metal, from the viewpoint of better connection stability. For each of the other metals, only one may be included, or two or more may be included.

Examples of the shape of the electrical conducting particles A include a spherical shape (a true spherical shape, a spheroidal shape, or the like), a flaky shape (a scaly shape or a flat shape), a dendritic shape (dendrite shape), a fibrous shape, and an irregular shape (polyhedron and the like). Among them, a spherical shape is preferable from the viewpoint that the thermal conductivity and the electrical conductivity in the thickness direction are better.

The content of the electrical conducting particles A in the thermally-conductive electrical conducting layer is preferably 10 to 70% by mass, more preferably 15 to 60% by mass, and further preferably 20 to 50% by mass based on 100% by mass of the total amount of the thermally-conductive electrical conducting layer. When the content is 10% by mass or more, the thermal conductivity and the electrical conductivity in the thickness direction are better. When the content is 70% by mass or less, the flexibility of the thermally-conductive electrical conducting layer is excellent.

### (Electrical Conducting Particles B)

As described above, the thermally-conductive electrical conducting layer includes the electrical conducting particles B having a median diameter smaller than the thickness of the thermally-conductive electrical conducting layer as the electrical conducting particles. The thermally-conductive electrical conducting layer includes the electrical conducting particles B, whereby spaces between the electrical conducting particles A are filled with the electrical conducting particles B, which improves the thermal conductivity and the electrical conductivity between the electrical conducting particles and makes the thermal conductivity and the electrical conductivity in the thickness direction of the thermally-conductive electrical conducting layer excellent.

The median diameter of the electrical conducting particles B is less than 100%, preferably 80% or less, more preferably 60% or less, further preferably 40% or less, and particularly preferably 30% or less based on the thickness of the thermally-conductive electrical conducting layer. When the median diameter of the electrical conducting particles B is 80% or less, it is possible to further improve the thermal conductivity and the electrical conductivity between the electrical conducting particles. The median diameter of the electrical conducting particles B is preferably 5% or more, more preferably 10% or more, and further preferably 15% or more based on the thickness of the thermally-conductive electrical conducting layer.

The median diameter of the electrical conducting particles B is preferably 1 to 25 μm, and more preferably 3 to 10 μm. When the median diameter is 1 μm or more, the thermal conductivity and the electrical conductivity in the thickness direction become higher. In addition, the dispersibility of the electrical conducting particles is good, and aggregation can be suppressed. When the median diameter is 25 μm or less, the close adhesion strength of the thermally-conductive electrical conducting layer to objects is better.

Examples of the electrical conducting particles B include, as illustrated and described as the electrical conducting particles A, metal particles, metal-coated resin particles, metal fibers, carbon fillers, and carbon nanotubes.

Among them, metal particles are preferable as the electrical conducting particles B, and silver particles, silver-coated copper particles, and silver-coated copper alloy particles are preferable. From the viewpoints of excellent thermal conductivity and electrical conductivity, suppressing the oxidation and aggregation of the electrical conducting particles, and being able to lower the cost of the electrical conducting particles, particularly silver-coated copper particles and silver-coated copper alloy particles are preferable.

Examples of the shape of the electrical conducting particles B include a spherical shape (a true spherical shape, a spheroidal shape, or the like), a flaky shape (a scaly shape or a flat shape), a dendritic shape (dendrite shape), a fibrous shape, an irregular shape (polyhedron or the like), a block shape, and a spike shape. Among them, a spherical shape, a dendritic shape, a block shape, and a spike shape are preferable. The reason for this is as follows: by making the shape of the electrical conducting particles B spherical, dendritic, block-like, or spike-like, the electrical conducting particles B form a network both in the plane direction and in the thickness direction, and an action of complementing thermal conduction in the thickness direction of the electrical conducting particles A can be thus expected. In contrast, in the case of a flaky shape, thermal conduction is performed in the plane direction, and the particles and the resin lie on top of one another in the vertical direction, and there is thus a tendency that thermal resistance becomes high in the thickness direction. The thermal conductivity and electrical conductivity of the entire thermally-conductive electrical conducting layer in the thickness direction improve in cooperation with the improvement in thermal conductivity and electrical conductivity in the plane direction and the thermal conductivity and the electrical conductivity in the thickness direction attributed to the electrical conducting particles A.

The content of the electrical conducting particles B in the thermally-conductive electrical conducting layer is preferably 10 to 70% by mass, more preferably 15 to 60% by mass, and further preferably 20 to 50% by mass based on 100% by mass of the total amount of the thermally-conductive electrical conducting layer. When the content is 10% by mass or more, the thermal conductivity and the electrical conductivity in the thickness direction are more exhibited. When the content is 70% by mass or less, the flexibility of the thermally-conductive electrical conducting layer is excellent.

The mass ratio of the electrical conducting particles A to the electrical conducting particles B [electrical conducting particles A/electrical conducting particles B] is preferably 0.1 to 10.0, more preferably 0.2 to 5.0, further preferably 0.3 to 3.0, and particularly preferably 0.5 to 2.0. With the mass ratio within the above range, the electrical conducting particles A and the electrical conducting particles B are blended in good balance, whereby the thermal conductivity and the electrical conductivity in the thickness direction as the thermally-conductive electrical conducting layer are superior.

The content (total amount) of the electrical conducting particles in the thermally-conductive electrical conducting layer is preferably 50 to 500 parts by mass, more preferably 100 to 400 parts by mass, and further preferably 150 to 300 parts by mass based on 100 parts by mass of the total amount of the binder component. With the content being 50 parts by mass or more, the content of the electrical conducting particles is sufficient, and the thermal conductivity and the electrical conductivity in the thickness direction are superior. With the content being 500 parts by mass or less, the contact opportunities between the electrical conducting particles are suppressed, a rise in the resistance value is suppressed, and the thermal conductivity and the electrical conductivity in the thickness direction are superior. In addition, the flexibility and formability of thermally-conductive electrical conducting layer is excellent.

### (Binder Component)

Examples of the binder component include thermoplastic resins, thermosetting type resins, and active energy ray-curable type compounds. Examples of the thermoplastic resins include polystyrene-based resins, vinyl acetate-based resins, polyester-based resins, polyolefin-based resins (for example, polyethylene-based resins and polypropylene-based resin compositions), polyimide-based resins, and acrylic resins. Only one of the thermoplastic resin may be used, or two or more of the thermoplastic resins may be used.

Examples of the thermosetting type resins include both of resins having thermosetting properties (thermosetting resins) and resins obtained by curing the thermosetting resins. Examples of the thermosetting resins include phenol-based resins, epoxy-based resins, urethane-based resins, melamine-based resins, alkyd-based resins, and silicone-based resin. Only one of the thermosetting type resin may be used, or two or more of the thermosetting type resins may be used.

Examples of the epoxy-based resins include bisphenol type epoxy-based resins, spiro ring type epoxy-based resins, naphthalene type epoxy-based resins, biphenyl type epoxy-based resins, terpene type epoxy-based resins, glycidyl ether type epoxy-based resins, glycidylamine type epoxy-based resins, and novolac type epoxy-based resins.

Examples of the bisphenol type epoxy-based resins include bisphenol A type epoxy-based resins, bisphenol F type epoxy-based resins, bisphenol S type epoxy-based resins, and tetrabromobisphenol A type epoxy-based resins. Examples of the glycidyl ether type epoxy-based resins include tris(glycidyloxyphenyl) methane and tetrakis(glycidyloxyphenyl) ethane. Examples of the glycidylamine type epoxy-based resins include tetraglycidyldiaminodiphenylmethane. Examples of the novolac type epoxy-based resins include cresol novolac type epoxy-based resins, phenol novolac type epoxy-based resins, α-naphthol novolac type epoxy-based resins, and brominated phenol novolac type epoxy-based resins.

Examples of the active energy ray-curable type compounds include both of compounds that can be cured by active energy ray irradiation (active energy ray-curable compounds) and compounds obtained by curing the active energy ray-curable compounds. The active energy ray-curable compounds are not particularly limited, and examples thereof include polymerizable compounds having one or more (preferably two or more) radical reactive groups (for example, (meth)acryloyl groups) in the molecule. Only one of the active energy ray-curable type compound may be used, or two or more of the active energy ray-curable type compounds may be used.

As the binder component, among them, thermosetting type resins are preferable. In this case, after the thermally-conductive electrical conducting layer is disposed on an object such as a printed circuit board or a shielded printed circuit board subjected to electromagnetic wave shielding measures, the binder component can be cured by pressurization and heating, and the adhesiveness of the lamination portion is good. For example, when the binder component is a thermosetting resin, the binder component after thermocompression bonding is a thermosetting type resin in which the thermosetting resin is cured.

When the binder component includes a thermosetting type resin, it may include a curing agent for accelerating a thermal curing reaction, as a component constituting the binder component. The curing agent can be appropriately selected according to the type of the thermosetting resin. Only one of the curing agent may be used, or two or more of the curing agents may be used.

The content of the binder component in the thermally-conductive electrical conducting layer is not particularly limited, and is preferably 5 to 50% by mass, more preferably 10 to 45% by mass, and further preferably 15 to 40% by mass based on 100% by mass of the total amount of the thermally-conductive electrical conducting layer. When the content is 5% by mass or more, the close adhesiveness to objects is better. When the content is 50% by mass or less, the electrical conducting particles can be sufficiently blended, and the thermal conductivity and the electrical conductivity in the thickness direction is better.

The thermally-conductive electrical conducting layer may contain other components other than the above components within a range that does not impair the effects intended by the present disclosure. Examples of the other components include components included in known or commonly used adhesives. Examples of the other components include a curing accelerator, a plasticizer, a flame retardant, an antifoaming agent, a viscosity adjusting agent, an antioxidant, a diluent, an anti-settling agent, a filler, a colorant, a leveling agent, a coupling agent, an ultraviolet absorbing agent, a tackifier resin, and an anti-blocking agent. For the other components, only one may be used, or two or more may be used. In addition, the thermally-conductive electrical conducting layer may include electrical conducting particles other than the electrical conducting particles A and the electrical conducting particles B, and the ratio thereof is, for example, 10 parts by mass or less, preferably 5 parts by mass or less, and more preferably 1 part by mass or less based on 100 parts by mass of the sum of the electrical conducting particles A and the electrical conducting particles B.

The thickness of the thermally-conductive electrical conducting layer is preferably 1 to 80 μm, more preferably 10 to 50 μm. When the thickness is 1 μm or more, the close adhesion strength to objects is better. When the thickness is 80 μm or less, the cost can be reduced, and products including the thermally-conductive electrical conducting layer can be designed thin. The thickness of the thermally-conductive electrical conducting layer is the thickness in the region in which the electrical conducting particles do not protrude (for example, the thickness T shown in FIG. 1). The thickness of the thermally-conductive electrical conducting layer when the adhesive component (binder component) constituting the thermally-conductive electrical conducting layer flows due to heating or the like and enters an opening formed in an object, or the like is the thickness of the thermally-conductive electrical conducting layer in the region in which the adhesive component does not enter the opening.

In the thermally-conductive electrical conducting layer, the electrical conducting particles A are preferably disposed to be aligned in the plane direction of the thermally-conductive electrical conducting layer as primary particles or aggregates of primary particles. When the electrical conducting particles A are disposed to be aligned, it is possible to easily adjust the thermal conductivity and electrical conductivity of the thermally-conductive electrical conducting layer in the thickness direction and in the plane direction. In addition, the thermal conductivity and electrical conductivity of the thermally-conductive electrical conducting layer in the thickness direction and in the plane direction can be more easily adjusted by adjusting the alignment shape or the distances between the particles at the time of disposing the electrical conducting particles A to be aligned.

Particularly, the electrical conducting particles A are preferably dotted and more preferably disposed to be aligned in a lattice point shape as primary particles or aggregates of primary particles in terms of the disposition shape when the thermally-conductive electrical conducting layer is observed from the upper surface (in the thickness direction). Examples of the lattice in the lattice point shape include quadrangular lattices such as a square lattice, triangular lattices such as a hexagonal lattice (equilateral triangular lattice) and a rhombic lattice, and parallelepiped lattices.

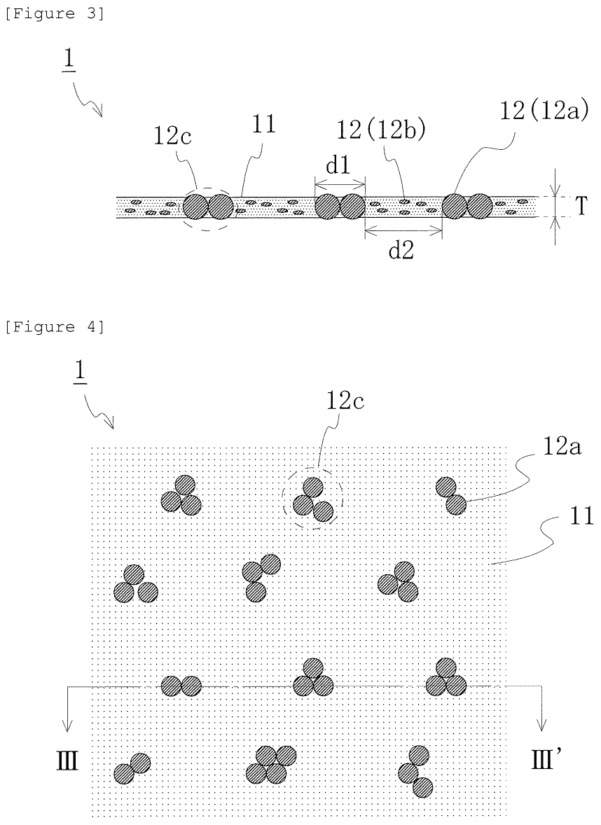

In a case where the electrical conducting particles A are disposed to be aligned in a dotted manner, the size of the particle dot when the thermally-conductive electrical conducting layer is observed from the upper surface (in the thickness direction) is preferably 30 to 500 μm and more preferably 50 to 200 μm. The size of the particle dot is defined as the maximum length in one primary particle or aggregate in one place (the distance between the distant end portions of the electrical conducting particles in the same particle dot) and is, for example, d1 shown in FIG. 3. In addition, the distance between the particle dots most adjacent to each other is preferably 50 to 1000 μm, and more preferably 200 to 700 μm. The distance between the particle dots is defined as the closest distance among the distances between the end portions of the primary particles or the aggregates belonging to mutually different particle dots and is, for example, d2 shown in FIG. 3.

FIG. 2 shows a top view of a thermally-conductive electrical conducting layer 1 shown in FIG. 1. FIG. 1 corresponds to an I-I′ cross-sectional view in FIG. 2. In FIG. 1 and FIG. 2, the electrical conducting particles A (12a) are disposed to be aligned in a dotted manner in a square lattice shape as primary particles.

FIG. 3 and FIG. 4 show an embodiment in which the electrical conducting particles A (12a) are disposed to be aligned in a dotted manner in an equilateral triangular lattice shape as aggregates (12c) of primary particles. FIG. 4 shows a top view of the thermally-conductive electrical conducting layer 1, and FIG. 3 corresponds to an III-III′ cross-sectional view in FIG. 4. In each of the dotted aggregates of primary particles, the number of the primary particles may be the same as each other or may be different from each other as shown in FIG. 4. In addition, as long as the electrical conducting particles are disposed to be aligned as the aggregates (12c) of the primary particles, the electrical conducting particles are considered to be disposed to be aligned even when the primary particles are arranged in a different manner in one aggregate (12c) of the primary particles.

In a case where the electrical conducting particles A are dotted, the number of the particles in the aggregate of the primary particles in one place is not particularly limited and can be selected as appropriate depending on desired thermal conductivity and electrical conductivity.

In the thermally-conductive electrical conducting layer, the resistivity is 2.0×10⁻⁵Ω·m or more, more preferably 1.0×10⁻⁴Ω·m or more, and further preferably 3.0×10⁻⁴Ω·m or more. When the resistivity is 2.0×10⁻⁵Ω·m or more, thermal conduction and electrical conduction in the plane direction are suppressed, and thermal conduction and electrical conduction in the thickness direction are excellent. The resistivity is, for example, 1.0×10¹⁰Ω·m or less and may be 1.0Ω·m or less.

The resistivity can be obtained by the following electrical conductivity test 1.

### [Electrical Conductivity Test 1]

The thermally-conductive electrical conducting layer (10 mm in length×30 mm in width) is laminated on a polyimide film, two nickel gold-plated copper foils are laminated on both ends of the thermally-conductive electrical conducting layer in the long direction, respectively, the thermally-conductive electrical conducting layer is cured as necessary, and the resistivity between the two nickel gold-plated copper foils is measured by the four-terminal method.

Regarding the thermally-conductive electrical conducting layer, the surface resistance value is preferably 1.0Ω or more, more preferably 1.5Ω or more, and further preferably 2.0Ω or more. When the surface resistance value is 1.0Ω or more, thermal conduction and electrical conduction in the plane direction are suppressed, and thermal conduction and electrical conduction in the thickness direction are superior. The surface resistance value is, for example, 1.0×10¹⁵Ω or less and may be 20Ω or less or 15Ω or less.

The surface resistance value can be obtained by the following electrical conductivity test 2.

### [Electrical Conductivity Test 2]

The thermally-conductive electrical conducting layer (10 mm in length×30 mm in width) is laminated on a polyimide film, two nickel gold-plated copper foils are laminated on both ends of the thermally-conductive electrical conducting layer in the long direction, respectively, the thermally-conductive electrical conducting layer is cured as necessary, and the surface resistance value between the two nickel gold-plated copper foils is measured by the four-terminal method.

Regarding the thermally-conductive electrical conducting layer, the electrical resistance value in the thickness direction is preferably 1.0Ω or less, more preferably 0.5Ω or less, and further preferably 0.1Ω or less. When the electrical resistance value in the thickness direction is 1.0Ω or less, electrical conduction between objects through the thermally-conductive electrical conducting layer becomes favorable.

The electrical resistance value in the thickness direction can be obtained by the following electrical conductivity test 3.

### [Electrical Conductivity Test 3]

The thermally-conductive electrical conducting layer is laminated on a SUS plate (thickness: 200 μm) by heating and pressurization under the conditions of temperature: 120° C. and pressure: 0.5 MPa for 5 s, the face on the thermally-conductive electrical conducting layer side is laminated on a printed circuit board for evaluation, and using a press machine, after evacuation for 60 s, the laminate is heated and pressurized under the conditions of temperature: 170° C. and pressure: 3.0 MPa for 30 min to prepare a board for evaluation. As the printed circuit board, a printed circuit board is used in which two copper foil patterns (thickness: 18 μm, line width: 3 mm) imitating a ground circuit are formed on a base member composed a polyimide film having a thickness of 12.5 μm, and an insulating adhesive (thickness: 13 μm) and a coverlay composed a polyimide film having a thickness of 25 μm are formed thereon. A circular opening simulating a ground connection portion having a diameter of 1 mm is formed in the coverlay. For the board for evaluation, the electrical resistance value between the copper foil patterns and the SUS plate is measured by a resistance meter and taken as the resistance value.

Regarding the thermally-conductive electrical conducting layer, the thermal conductivity in the thickness direction is preferably 5.0 W/mK or more, more preferably 7.0 W/mK or more, and further preferably 10.0 W/mK or more. When the thermal conductivity in the thickness direction is 5.0 W/mK or more, heat dissipation from an object through the thermally-conductive electrical conducting layer becomes favorable.

The thermally-conductive electrical conducting layer is preferably for printed circuit board applications, particularly preferably for flexible printed circuit board (FPC) applications. The thermally-conductive electrical conducting layer is excellent in the connection stability between objects that are conductive members while being economically excellent, and the connection stability is maintained even when the thermally-conductive electrical conducting layer is subjected to high temperature. Therefore, the thermally-conductive electrical conducting layer can be preferably used as an electromagnetic wave shielding film or an electrical conducting bonding film for a printed circuit board (particularly for an FPC). The electrical conducting bonding film is intended for the attachment of an electrical conducting (metal) reinforcing plate to a printed circuit board, and examples of the electrical conducting bonding film also include a ground connection drawing film intended to allow electromagnetic waves that enter or are produced in a printed circuit board to escape externally.

A separate film may be stacked on at least one face of the thermally-conductive electrical conducting layer. That is, the thermally-conductive electrical conducting layer may be provided as a stack including a separate film and the thermally-conductive electrical conducting layer formed on the release face of the separate film. The separate film is peeled at the time of use.

The thermally-conductive electrical conducting layer can be manufactured by a known or commonly used manufacturing method. Examples include applying (coating) a composition forming the thermally-conductive electrical conducting layer on a temporary substrate such as a separate film or a substrate, and removing the solvent and/or partially cure the composition, as needed, to form the thermally-conductive electrical conducting layer. In addition, in a case where the electrical conducting particles A are disposed to be aligned, the electrical conducting particles A may be embedded in a desired position after the application of a composition not containing the electrical conducting particles A. In addition, the thermally-conductive electrical conducting layer may be formed by arranging the electrical conducting particles A to be disposed to be aligned as intended on a temporary base material or a base material, then, applying a composition not containing the electrical conducting particles, and then removing the solvent, and/or partially curing the electrical conducting particles as necessary. In the case of being disposed separately, the electrical conducting particles A may be disposed in a state of a composition in which the binder component and a curing agent have been mixed together. When the electrical conducting particles A are disposed as aggregates of primary particles, the aggregates may be made into aggregates in which the primary particles spread in the plane direction by applying pressure in the plane direction.

The composition includes, for example, a resolvent (solvent), in addition to the above components. Examples of the resolvent include toluene, acetone, methyl ethyl ketone, methanol, ethanol, propanol, and dimethylformamide. The solid concentration of the composition is appropriately set according to the thickness of the thermally-conductive electrical conducting layer to be formed, and the like.

For the application of the composition, a known coating method may be used. For example, a coater such as a gravure roll coater, a reverse roll coater, a kiss roll coater, a lip coater, dip roll coater, a bar coater, a knife coater, a spray coater, a comma coater, a direct coater, or a slot die coater may be used.

[Printed Circuit Board with Reinforcing Member]

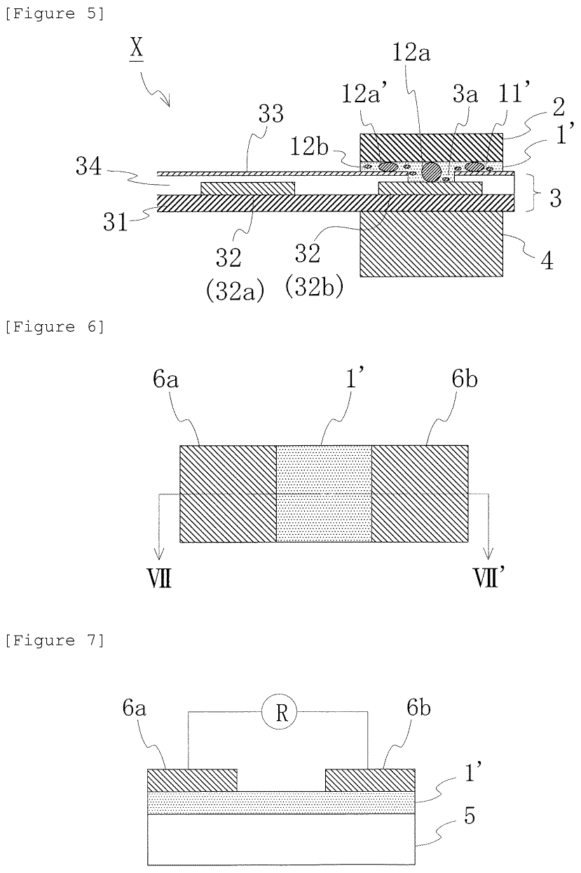

FIG. 5 shows an example in which the thermally-conductive electrical conducting layer is applied to a printed circuit board with a reinforcing member. As shown in FIG. 5, a printed circuit board with a reinforcing member (X) that is one embodiment of a printed circuit board with a reinforcing member includes a printed circuit board (3), a thermally-conductive electrical conducting layer (1′) provided on the printed circuit board (3), and a reinforcing member (2) having electrical conductivity provided on the thermally-conductive electrical conducting layer (1′).

The printed circuit board (3) has a base member (31), a circuit pattern (32) partially provided on a surface of the base member (31), an insulating protective layer (33) covering and insulating and protecting the circuit pattern (32), and an adhesive (34) for covering the circuit pattern (32) and adhering the circuit pattern (32) and the base member (31) to the insulating protective layer (33). The circuit pattern (32) includes a plurality of signal circuits (32a) and a ground circuit (32b). An opening (through hole) (3a) passing through the adhesive (34) and the insulating protective layer (33) in the thickness direction is formed in the adhesive (34) and the insulating protective layer (33) on the ground circuit (32b).

The thermally-conductive electrical conducting layer (1′) is adhered to the insulating protective layer (33) surface of the printed circuit board (3) so as to cover and block the opening (3a), and a binder component (adhesive component) (11′) fills the opening (3a). The thermally-conductive electrical conducting layer (1′) is formed of electrical conducting particles A (12a), (12a′) and electrical conducting particles B (12b) and the binder component (adhesive component) (11′). The thermally-conductive electrical conducting layer (1′) has a thick film portion in which the thickness of the resin layer is relatively thick, and a thin film portion in which the thickness of the resin layer is relatively thin. The thick film portion corresponds to the portion filling the opening (3a), and the thin film portion corresponds to the portion located between the insulating protective layer (33) and the reinforcing member (2). The electrical conducting particles A (12a) in the thick film portion are located between the reinforcing member (2) and the ground circuit (32b) and preferably provides conduction between the reinforcing member (2) and the ground circuit (32b) while being in contact with them. The thickness of the resin layer in the thick film portion is, for example, 50% or more (preferably 70% or more, more preferably 90% or more) of the median diameter of the electrical conducting particles A (12a) in the resin layer thickness direction in the thick film portion. The electrical conducting particles A (12a′) in the thin film portion are located between the reinforcing member (2) and the insulating protective layer (33), compressively deformed by pressure, and preferably in contact with the reinforcing member (2) and the insulating protective layer (33). The thickness of the resin layer in the thin film portion is, for example, 50% or more (preferably 70% or more, more preferably 90% or more) of the median diameter of the electrical conducting particles A (12a′) in the resin layer thickness direction in the thin film portion. With the printed circuit board with the reinforcing member X having such a structure, the ground member (32b) and the reinforcing member (2) are brought into conduction via the electrical conducting particles (12), the reinforcing member (2) functions as an external connection conducting layer, and the reinforcing member (2) surface is electrically connected to an external ground member.

When thermocompression bonding is performed in order to form the thermally-conductive electrical conducting layer (1′), the electrical conducting particles A (12a) enter an opening (3a) and sufficiently exhibit the thermal conductivity and the electrical conductivity (anisotropic conductivity) in the thickness direction. The electrical conducting particles A (12a′) that are present in a thin film portion without entering the opening (3a) sufficiently exhibit the thermal conductivity and the electrical conductivity (anisotropic conductivity) in the thickness direction as the electrical conducting particles A (12a). On the other hand, the electrical conducting particles B (12b) are likely to exhibit thermal conductivity in the plane direction and isotropic electrical conductivity. This thermal conductivity in the plane direction and isotropic conductivity allows thermal conductivity and electrical conductivity to be exhibited in the plane direction and the thickness direction of between each particle of the electrical conducting particles A (12a), the electrical conducting particles A (12a′), and the electrical conducting particles B (12b). Thus, in the thermally-conductive electrical conducting layer (1′), by combining and allowing the thermal conductivity in the plane direction and the anisotropic conductivity of the electrical conducting particles A (12a), (12a′) and the thermal conductivity in the plane direction and the isotropic conductivity of the electrical conducting particles B (12b) to be exhibited, the thermal conductivity and the electrical conductivity in the thickness direction is excellent as the thermally-conductive electrical conducting layer.

The thermally-conductive electrical conducting layer (1′) can be obtained, for example, as follows: the thermally-conductive electrical conducting layer (1) before flowing or before curing that forms the thermally-conductive electrical conducting layer (1′) is laminated on a surface of the reinforcing member (2) as needed, then laminated on the insulating protective layer (33) in the printed circuit board (3), and subsequently thermocompression bonded by flowing or curing the binder component (11) by heating, and thus the electrical conducting particles A (12a) are sandwiched between the reinforcing member (2) and the insulating protective layer (33) and compressively deformed to form the electrical conducting particles A (12a′), and while the binder component (adhesive component) (11) is adhered to the insulating protective layer (33), the binder component (11) is flowed and the binder component (11), the electrical conducting particles A (12a), and the electrical conducting particles B (12b) fill the opening (3a), and cured as needed, to form the binder component (11′).

The mounting site provided on the face of the printed circuit board (3) opposite to the reinforcing member (2) is adapted so that the electronic component (4) is connected to the mounting site. The reinforcing member (2) is disposed opposed to the mounting site to which the electronic component (4) is to be connected. Thus, the reinforcing member (2) reinforces the mounting site for the electronic component (4). The reinforcing member (2) having electrical conductivity is electrically connected to the ground circuit (32b) in the printed circuit board (3) via the thermally-conductive electrical conducting layer (1′). Thus, the reinforcing member (2) is kept at the same potential as the ground circuit (32b) and therefore shields the mounting site for the electronic component (4) from external noise such as electromagnetic waves.

### EXAMPLES

One embodiment of the thermally-conductive electrical conducting layer of the present disclosure will be described in more detail below based on Examples, but the thermally-conductive electrical conducting layer of the present disclosure is not limited only to these Examples.

### Example 1

55 Parts by mass of a bisphenol A-type epoxy-based resin (trade name “jER1256”, manufactured by Mitsubishi Chemical Corporation), 0.05 parts by mass of a curing agent (trade name “ST14”, manufactured by Mitsubishi Chemical Corporation), and 45 parts by mass of a silver-coated copper powder (electrical conducting particles B, dendritic shape) were blended in toluene so that the amount of solids was 20% by mass, and the blend was stirred and mixed to prepare an adhesive composition. The obtained adhesive composition was applied to the release-treated face of a PET film having a surface release-treated to form a coated film. In addition, 5 parts by mass of a bisphenol A type epoxy-based resin (trade name “jER1256”, manufactured by Mitsubishi Chemical Corporation), 0.005 parts by mass of a curing agent (trade name “ST14”, manufactured by Mitsubishi Chemical Corporation), and 95 parts by mass of metal particles (composition: Ag 3.5/Cu 0.75/Sn 95.75 (the numerical value represents mass ratio), thermal conductivity: 20 W/mK or more, 20% compressive strength at 170° C.: 20.0 MPa, electrical conducting particles A, and a spherical shape) were blended in cyclohexanone so that the amount of solids was 20% by mass, dotted in an equilateral triangular lattice shape (the number of the metal particles per place was one to five) on the coated film, and then the solvent was removed by heating the blend at 150° C. for one minute, thereby forming a thermally-conductive electrical conducting adhesive layer (the size of one particle dot was approximately 150 μm, the distance between the particle dots was approximately 250 μm).

The median diameters (D50) of the electrical conducting particles A and B used are as shown in Table 1.

### Examples 2 to 3 and Comparative Example 1

The thermally-conductive electrical conducting adhesive layers were made in the same manner as Example 1 except that the kind of the electrical conducting particles in the thermally-conductive electrical conducting adhesive layer, the content of the electrical conducting particles, the thickness of the thermally-conductive electrical conducting adhesive layer, and the like were changed as shown in Table 1. The median diameters (D50) of the electrical conducting particles used in each Example are as shown in Table 1. The electrical conducting particles A that were used in Examples 2 and 3 and Comparative Example 1 are all the same as the electrical conducting particles A in Example 1. In addition, the electrical conducting particles B that were used in Examples 2 and 3 and Comparative Example 1 are all silver-coated copper powders.

### (Evaluation)

The electrical conducting particles used in the Examples and the Comparative Example, and the thermally-conductive electrical conducting adhesive layers obtained in the Examples and the Comparative Example were evaluated as follows. The evaluation results are described in Table 1.

### (1) Median Diameter

The median diameter of electrical conducting particles was measured using a flow type particle image analysis apparatus (trade name “FPIA-3000”, manufactured by SYSMEX CORPORATION). Specifically, measurement was performed using objective lens 10× by a bright field optical system in the LPF measurement mode with an electrical conducting particle dispersion adjusted at a concentration of 4000 to 20000 particles/μl. The electrical conducting particle dispersion was prepared by adding 0.1 to 0.5 ml of a surfactant to a sodium hexametaphosphate aqueous solution adjusted at 0.2% by mass, and adding 0.1+0.01 g of electrical conducting particles that were a measurement sample. The suspension in which the electrical conducting particles were dispersed was subjected to 1 to 3 min dispersion treatment by an ultrasonic disperser and subjected to the measurement. The median diameter of the electrical conducting particles obtained by the measurement is shown in Table 1.

### (2) Surface Resistance Value

First, a test piece shown in FIG. 6 and FIG. 7 was made. FIG. 7 corresponds to a VII-VII′ cross-sectional view in FIG. 6. Specifically, the thermally-conductive electrical conducting adhesive layer (10 mm in length and 30 mm in width) made in each of the Examples and the Comparative Example was temporarily laminated on a polyimide film 5 (10 mm in length, 30 mm in width, and 25 μm in thickness) by heating and pressurizing under the conditions of temperature: 120° C. and pressure: 0.5 MPa for 5 s. In addition, two nickel gold-plated copper foils 6a and 6b (10 mm in length, 10 mm in width, and 6 μm in thickness) were temporarily laminated on both ends of the thermally-conductive electrical conducting adhesive layer in the long direction, respectively, by heating and pressurizing under the conditions of temperature: 120° C. and pressure: 0.5 MPa for 5 s. Next, the product was heated under the conditions of temperature: 170° C. and normal pressure for 60 s and then heated and pressurized under the conditions of temperature: 170° C. and pressure: 2 MPa for 240 s using a press machine. After that, the product was heated at a temperature: 150° C. for one hour, and the thermally-conductive electrical conducting adhesive layer was cured to form a thermally-conductive electrical conducting layer 1′. A test piece for evaluating the surface resistance value was made as described above. In addition, the surface resistance value between the two nickel gold-plated copper foils 6a and 6b was measured by the four-terminal method.

### (3) Resistivity

Regarding the test piece for evaluating the surface resistance value, the resistivity between the two nickel gold-plated copper foils 6a and 6b was measured using a measuring instrument A (trade name “RM3544”, manufactured by Hioki E. E. Corporation) or a measuring instrument B (trade name “8349A ULTRA HIGH RESISTANCE METER (50 V)”, manufactured by ADC Corporation). The resistivity was first measured with the measuring instrument A, in a case where the resistivity was measurable, the detected value was regarded as the resistivity, and, in a case where the resistance value was high and was unmeasurable, the resistivity was measured with the measuring instrument B, and the detected value was regarded as the resistivity.

### (4) Thermal Conductivity Test

A bulk body having a thickness of 1 mm or more was made by laminating each of the thermally-conductive electrical conducting adhesive layers made in the Examples and the Comparative Example, and the thermal diffusivity was measured by the laser flash method using a thermophysical property measuring instrument (trade name “TA35”, manufactured by Bethel Vietnam Co., Ltd.). In addition, regarding the thermally-conductive electrical conducting adhesive layers, the specific heat was measured by the DSC method using a differential scanning calorimeter (trade name “X-DSC7000” type, manufactured by Hitachi High-Tech Science Corporation). In addition, regarding a thermally-conductive electrical conducting adhesive layer, the specific gravity was measured by the immersion method using an electronic hydrometer (trade name “EW-300SG”, Alfa Mirage Co., Ltd.). In addition, the thermal conductivity in the thickness direction was calculated by calculation using the thermal diffusivity, the specific heat, and the specific gravity obtained above.

TABLE 1

| | Exam- | Exam- | Exam- | Comparative |
|---|---|---|---|---|
| | ple 1 | ple 2 | ple 3 | Example 1 |
| Thickness of resin | 17.9 | 17.5 | 19.8 | 20.1 |
| layer [μm] | | | | |
| Kind of electrical | Spherical | Spherical | Spherical | Spherical |
| conducting | 35 μm | 35 μm | 35 μm | 35 μm |
| particles A | | | | |
| Proportion of | 37.9 | 37.9 | 30.7 | 30.7 |
| electrical conducting | | | | |
| particles A [% by mass] | | | | |
| Kind of electrical | Dendrite | Spherical | Spherical | Flake |
| conducting | 5 μm | 5 μm | 5 μm | 5 μm |
| particles B | | | | |
| Proportion of | 28.0 | 28.0 | 41.7 | 41.7 |
| electrical conducting | | | | |
| particles B [% by mass] | | | | |
| Total proportion of | 65.9 | 65.9 | 72.4 | 72.4 |
| electrical conducting | | | | |
| particles [% by mass] | | | | |
| Thermal conductivity | 7.96 | 11.92 | 13.14 | 1.42 |
| in thickness | | | | |
| direction [W/mK] | | | | |
| Surface resistance | 14.46 | 1.86E+10 | 1.69E+10 | 0.977 |
| value [Ω] | | | | |
| Resistivity [Ω · m] | 2.58E−04 | 3.25E+05 | 3.34E+05 | 1.96E−05 |
| Measuring instrument | A | B | B | A |

The thermally-conductive electrical conducting adhesive layers of the Examples were evaluated to have a high resistivity and be excellent in terms of thermal conductivity and electrical conductivity in the thickness direction. On the other hand, in the case of a low resistivity (Comparative Example 1), the thermal conductivity and the electrical conductivity in the thickness direction were evaluated to be insufficient.

Hereinafter, variations of the present disclosure will be described.

### [Additional Note 1]

A thermally-conductive electrical conducting layer comprising a binder component and electrical conducting particles, wherein the electrical conducting particles comprise electrical conducting particles A having a median diameter larger than a thickness of the thermally-conductive electrical conducting layer and having a thermal conductivity of 20 W/mK or more, and electrical conducting particles B having a median diameter smaller than the thickness of the thermally-conductive electrical conducting layer, and a resistivity is 2.0×10⁻⁵Ω·m or more.

### [Additional Note 2]

The thermally-conductive electrical conducting layer according to Additional Note 1, wherein the electrical conducting particle A are disposed to be aligned in a plane direction of the thermally-conductive electrical conducting layer as primary particles or aggregates of primary particles.

### [Additional Note 3]

The thermally-conductive electrical conducting layer according to Additional Note 2, wherein the electrical conducting particle A are disposed to be dotted as primary particles or aggregates of primary particles.

### [Additional Note 4]

The thermally-conductive electrical conducting layer according to any one of Additional Notes 1 to 3, wherein a thermal conductivity in a thickness direction is 5.0 W/mK or more.

### [Additional Note 5]

The thermally-conductive electrical conducting layer according to any one of Additional Notes 1 to 4, wherein an electrical resistance value in the thickness direction is 0.1Ω or less.

### [Additional Note 6]

The thermally-conductive electrical conducting layer according to any one of Additional Notes 1 to 5, wherein a median diameter of the electrical conducting particles A is 105% to 1000% based on the thickness of the thermally-conductive electrical conducting layer, and a median diameter of the electrical conducting particles B is 5% to 80% based on the thickness of the thermally-conductive electrical conducting layer.

### REFERENCE SIGNS LIST

X printed circuit board with a reinforcing member
1, 1′ thermally-conductive electrical conducting layer
11, 11′ binder component (adhesive component)
12 electrical conducting particles
12a, 12a′ electrical conducting particles A
12b electrical conducting particles B
12c aggregate of electrical conducting particles A
2 reinforcing member
3 printed circuit board
31 base member
32 circuit pattern
32a signal circuit
32b ground circuit
33 insulating protective layer
34 adhesive
4 electronic component
5 polyimide film
6a, 6b nickel gold-plated copper foil

1. A thermally-conductive electrical conducting layer comprising a binder component and electrical conducting particles, wherein
the electrical conducting particles comprise electrical conducting particles A having a median diameter larger than a thickness of the thermally-conductive electrical conducting layer and having a thermal conductivity of 20 W/mK or more, and electrical conducting particles B having a median diameter smaller than the thickness of the thermally-conductive electrical conducting layer, and
a resistivity is 2.0×10⁻⁵Ω·m or more.

2. The thermally-conductive electrical conducting layer according to claim 1, wherein the electrical conducting particle A are disposed to be aligned in a plane direction of the thermally-conductive electrical conducting layer as primary particles or aggregates of primary particles.

3. The thermally-conductive electrical conducting layer according to claim 2, wherein the electrical conducting particle A are disposed to be dotted as primary particles or aggregates of primary particles.

4. The thermally-conductive electrical conducting layer according to claim 1, wherein a thermal conductivity in a thickness direction is 5.0 W/mK or more.

5. The thermally-conductive electrical conducting layer according to claim 1, wherein an electrical resistance value in a thickness direction is 0.1Ω or less.

6. The thermally-conductive electrical conducting layer according to claim 1, wherein a median diameter of the electrical conducting particles A is 105% to 1000% based on the thickness of the thermally-conductive electrical conducting layer, and a median diameter of the electrical conducting particles B is 5% to 80% based on the thickness of the thermally-conductive electrical conducting layer.
